(19) United States
(12) Patent Application Publication
(10) Pub. No.: US 2022/0230971 A1
(43) Pub. Date: Jul. 21, 2022

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Qiangwei Zhang, Wuhan (CN); Zongke Xu, Wuhan (CN); Bin Yuan, Wuhan (CN)

(73) Assignee: Yangtze Memory Technologies Co., Ltd.

(21) Appl. No.: 17/352,252

(22) Filed: Jun. 18, 2021

Related U.S. Application Data
(63) Continuation of application No. PCT/CN2021/083513, filed on Mar. 29, 2021.

(30) Foreign Application Priority Data
Jan. 21, 2021 (CN) 202110083408.X

(51) Int. Cl. H01L 23/00; H01L 23/535; H01L 27/11556; H01L 27/11582; H01L 21/768

(52) U.S. Cl. CPC H01L 23/562; H01L 23/535; H01L 21/76895; H01L 27/11582; H01L 21/76805; H01L 27/11556

(57) ABSTRACT

Three-dimensional (3D) memory devices and methods for forming the same are disclosed. In certain aspects, a 3D memory device includes a substrate, a stack structure laterally formed on the substrate and having a central area and a staircase area, a plurality of channel structures extending vertically in the central area, a plurality of dummy channel structures extending vertically in the staircase area, and a plurality of contact plugs formed in the staircase area and being electrically connected to the stack structure. A vertical projection of at least one of the dummy channel structures on a lateral surface of the substrate includes a two-dimensional shape with directionality.

### CROSS-REFERENCE TO RELATED APPLICATIONS

This application is continuation of International Application No. PCT/CN2021/083513, filed on Mar. 29, 2021, entitled “THREE-DIMENSIONAL MEMORY DEVICES AND METHODS FOR FORMING THE SAME,” which is hereby incorporated by reference in its entirety. This application also claims the benefit of priority to CN Patent Application No. 202110083408.X filed on Jan. 21, 2021, which is incorporated herein by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

3D memory devices and fabrication methods thereof are disclosed herein.

In one aspect, a 3D memory device includes a substrate, a stack structure laterally formed on the substrate and having a central area and a staircase area, a plurality of channel structures extending vertically in the central area, a plurality of dummy channel structures extending vertically in the staircase area, and a plurality of contact plugs formed in the staircase area and being electrically connected to the stack structure. A vertical projection of at least one of the dummy channel structures on a lateral surface of the substrate includes a two-dimensional shape with directionality.

In another aspect, a method for forming a 3D memory device is provided. A substrate is provided. A stack structure is formed laterally on the substrate and includes a central area and a staircase area. A plurality of dummy channel structures are formed and extend vertically in the staircase area. A vertical projection of at least one of the dummy channel structures on a lateral surface of the substrate includes a two-dimensional shape with directionality. A plurality of channel structures are formed and extend vertically in the central area. A plurality of contact plugs are formed in the staircase area and are electrically connected to the stack structure.

In still another aspect, a system includes a 3D memory device configured to store data and a memory controller coupled to the 3D memory device and configured to control the 3D memory device. The 3D memory device includes a substrate, a stack structure laterally formed on the substrate and having a central area and a staircase area, a plurality of channel structures extending vertically in the central area, a plurality of dummy channel structures extending vertically in the staircase area, and a plurality of contact plugs formed in the staircase area and being electrically connected to the stack structure. A vertical projection of at least one of the dummy channel structures on a lateral surface of the substrate includes a two-dimensional shape with directionality.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a diagram of an exemplary system for fabricating a semiconductor chip using photolithography, according to some aspects of the present disclosure.

FIG. 2A illustrates a top view of a semiconductor chip having a designed pattern.

FIG. 2B illustrates an enlarged top view of a semiconductor chip having a designed pattern.

FIG. 2C illustrates an enlarged top view of a semiconductor chip having a final pattern.

FIG. 3A illustrates a side view of a cross-section of an exemplary 3D memory device, according to some aspects of the present disclosure.

FIG. 3B illustrates an enlarged top view of an upper surface of 3D memory device shown in FIG. 3A, according to some aspects of the present disclosure.

FIG. 4 illustrates a top view of a semiconductor chip having a designed pattern, according to some aspects of the present disclosure.

FIGS. 5A-5M illustrate a fabrication process for forming an exemplary 3D memory device, according to some implementations of the present disclosure.

FIG. 6 illustrates a flowchart of a method for forming an exemplary 3D memory device, according to some implementations of the present disclosure.

FIG. 7 illustrates a block diagram of an exemplary system having a 3D memory device, according to some aspects of the present disclosure.

FIG. 8A illustrates a diagram of an exemplary memory card having a 3D memory device, according to some aspects of the present disclosure.

FIG. 8B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 180 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent or entirety of an underlying or overlying structure. Further, a layer can be a region of a homogeneous or heterogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

In semiconductor chip fabrication, photolithography is commonly used to create patterns on the surface of a semiconductor substrate. Similar to the patterning process in photography, where light is directed towards photosensitive materials coated on the film, photolithography guides light to photosensitive chemicals disposed on the semiconductor substrate, often in the form of a layer of photoresist, thereby removing certain parts of the photosensitive chemicals and exposing portions of the layer located underneath the photoresist layer. Thereafter, the exposed portions may be etched to create hole structures by dry etching, wet etching, or other suitable etching methods. Then a deposition process (e.g., chemical vapor deposition (CVD), atomic layer deposition (ALD), physical vapor deposition (PVD), electrochemical deposition (ECD), molecular beam epitaxy, or other suitable deposition methods) is carried out to grow, coat, or otherwise transfer a material onto the substrate. The result of this process creates various types of layers or films, such as a semiconductor channel, a dummy channel, etc., on the surface of the semiconductor substrate that serve their respective functionalities.

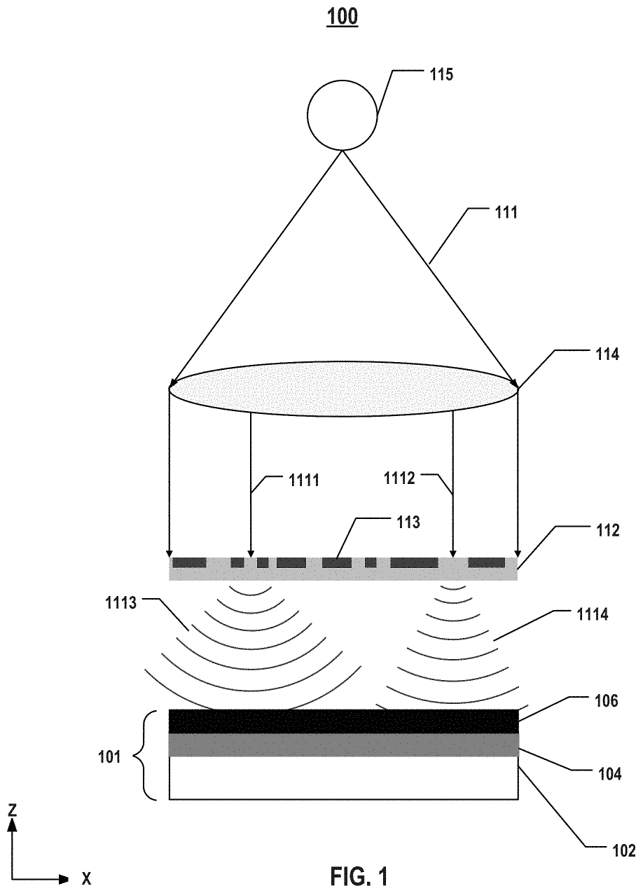

FIG. 1 illustrates a diagram of an exemplary system 100 for fabricating a semiconductor chip using photolithography, according to some aspects of the present disclosure. The semiconductor chip includes an intermediate structure 101, which may be used to form a 3D NAND memory device, a system-on-chip (SOC), or other integrated circuit (IC) chips. Intermediate structure 101 may have a substrate 102, which may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 102 is a thinned substrate (e.g., a semiconductor layer), which is thinned by grinding, etching, chemical mechanical polishing (CMP), or any combination thereof. It is noted that x and z axes are included in FIG. 1 to further illustrate the spatial relationship of the components in system 100. Substrate 102 may include two lateral surfaces (e.g., a top surface and a bottom surface) extending laterally in the x-direction (i.e., one lateral direction). As used herein, whether one component (e.g., a layer or a device) is “on,” “above,” “below,” or “beneath” another component (e.g., a layer or a device) of a substrate or a system is determined relative to the semiconductor substrate (e.g., substrate 102) in the z-direction (i.e., the vertical direction) when the substrate is positioned in the lowest plane of the semiconductor chip in the z-direction. The same notion for describing spatial relationships is applied throughout the present disclosure unless specified otherwise.

In some aspects consistent with the present disclosure, the semiconductor chip may include a layer 104. Depending on the types of the semiconductor chip, layer 104 may be a dielectric layer, a sacrificial layer, an oxide layer, a conductor layer, an insulation layer, or any other suitable films of materials. Before forming layer 104, substrate 102 may need to be cleaned to remove any contamination present on its surface by, for example, wet chemical treatment. Substrate 102 may be heated to vaporize any moisture thereon, for example, at a temperature of at least 150° C. for 10 to 20 minutes. Subsequently, layer 104 may be formed by deposition (including but not limited to CVD, ALD, PVD, ECD, or any combination thereof) on substrate 102. Layer 104 may be partially exposed for etching after one or more portions of photoresist disposed thereon are removed by photolithography.

According to the present disclosure, a photoresist layer 106 may be formed on substrate 102 or layer 104, depending on the applications of intermediate structure 101. Photoresist layer 106 may include a light-sensitive organic material, such as diazonaphthoquinone (DNQ), methyl methacrylate, or the like. In some implementations, photoresist layer 106 may be deposited on the top surface of layer 104 by spin coating. Spin coating enables photoresist layer 106 to be formed as a thin film with uniform thickness. In other implementations, suitable deposition materials that achieve the same result of uniformity may also be employed to form photoresist layer 106. After formation, photoresist layer 106 may be exposed to light in order to create a pattern thereon. The light may cause chemical reactions in certain exposed areas of photoresist layer 106 so that the exposed portions (for positive photoresist) or the unexposed portions (for negative photoresist) may be soluble in a developer that can carry those portions away from intermediate structure 101, therefore creating a pattern in photoresist layer 106. The layer below photoresist layer 106 may thus be exposed for subsequent etching, deposition, or both to form components of an integrated circuit.

In some aspects of the present disclosure, a photomask 112 may be used to direct light onto the top surface of intermediate structure 101 in a certain pattern, as shown in FIG. 1. The light may be emitted from a light source 115 and become light 111. Light source 115 may employ any light source suitable for photolithography. In some implementations, light source 115 may be a laser light emitter that emits light having a wavelength in the range of ultraviolet (UV), deep ultraviolet (DUV), extreme ultraviolet (EUV), or beyond extreme ultraviolet (BEUV). For example, an EUV light source is typically used in manufacturing semiconductor chips with a process node of 10 nm or below. In some implementations, a condenser lens 114 may be provided between light source 115 and photomask 112 to direct light 111 towards the surface of photomask 112 rather than emit elsewhere, so that energy loss can be reduced. A plurality of parallel light beams directed by condenser lens 114, such as light beams 1111 and 1112, may illuminate onto photomask 112.

Photomask 112 may be a plate made of an opaque material that has certain holes, or transparent or translucent portions that allow light to pass through (hereinafter non-opaque portions). Light may be blocked from passing through by portions of photomask 112 that are neither holes nor transparent/translucent (hereinafter opaque portions), such as portions 113. The composition and materials of photomask 112 may be selected with consideration of the wavelength of light 111 emitted from light source 115. In some implementations, photomask 112 may have a chromium layer on a quartz substrate. In other implementations, photomask 112 may include multiple alternating layers of molybdenum and silicon by reflecting light through these layers. The non-opaque portions may form a layout to direct the projection of light onto the surface of intermediate structure 101, which may be coated with photoresist layer 106, as described above. Although only one plate is shown in FIG. 1 that forms photomask 112, in other implementations consistent with the present disclosure, photomask 112 may include a number of masks, each of which may reproduce a layer. These layouts collectively correspond to a designed pattern. Such a plurality of photomasks 112 are also known as a photomask set. In other implementations, photomask 112 may include one or more phase-shift masks that utilize the phase change of the light as a result of the different optical thicknesses of the masks.

During the manufacturing process, it is desirable that, by photolithography through photomask 112, the pattern produced onto intermediate structure 101 resembles or equates to the designed pattern, so that the finished semiconductor chip will have layouts matching the original design. However, deviations or distortions of the produced pattern from the designed pattern are often inevitable, such as broader or narrower line widths, protrusions or concaves on a flat side, rounded corners, etc. Such errors may be attributed to diffraction of light 111, process effects, or both. Diffraction occurs when light, propagating as waves, passes through an opening or aperture, which effectively becomes a secondary source of the propagating waves. For example, as shown in FIG. 1, after reaching the openings on photomask 112, light beams 1111 and 1112 are diffracted as light waves 1113 and 1114, respectively. Generally, the smaller the opening, the more quickly the diffracted light diverges, and the larger the spot size is on the surface of intermediate structure 101. With respect to process effects, as the process node and the wavelength of light used in the process continue to decrease in recent years, it becomes increasingly difficult for the light to maintain its edge placement integrity. Therefore, compensation techniques are needed to correct these deviations and distortions of the pattern produced on the substrate so that the electrical features of the semiconductor devices will not be significantly altered from the designed features.

Consistent with the present disclosure, one of the compensation techniques is known as optical proximity correction (OPC). OPC may be employed to change the layouts on photomask 112 to account for, reduce, or even eliminate the various image errors of the pattern projected onto the substrate. Computer-aided design tools may create a virtual photomask that includes a simulated pattern corresponding to the designed pattern, and may also simulate the result of the optimization to find out which corrected virtual photomask has a layout that could be used to produce the final pattern on a substrate without significantly altering the intended electrical properties.

In some 3D NAND memory devices, to increase the storage capacity per unit area of such devices, semiconductor designers may choose one or more approaches, such as increasing the storage capacity of each memory cell, adding levels to a semiconductor structure of the device, increasing the number of cells by shrinking the size of each memory cell, etc. In one example, the number of levels of the semiconductor structure is 32 or even higher. As the height of the semiconductor structure increases, it becomes more difficult to maintain its robustness. When an external force is applied to the memory device, the electrical wiring in the semiconductor structure tends to bend or even break, rendering the device unusable.

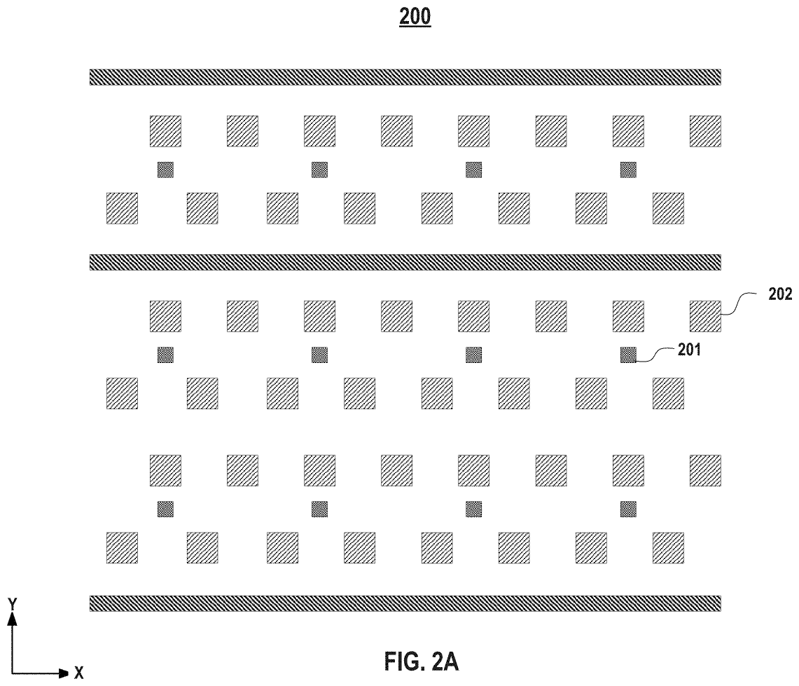

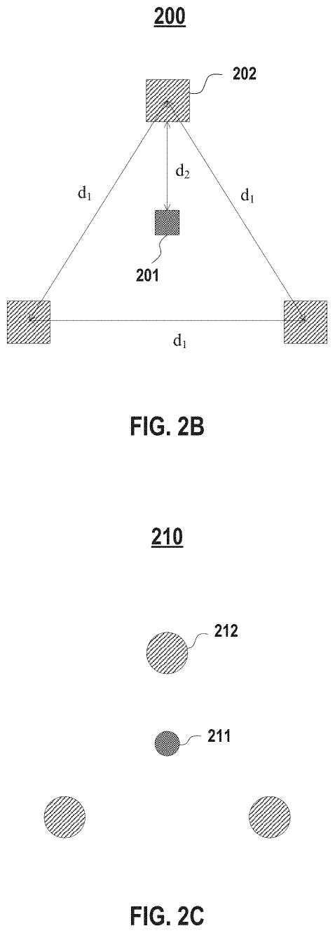

One solution to the above problem is to provide a dummy channel structure in the substrate of the semiconductor structure. FIG. 2A illustrates a top view of a semiconductor chip having a designed pattern 200. The top view is the view from above along the vertical direction (i.e., the z-direction) and shows a lateral surface of designed pattern 200. The lateral surface is defined by two lateral directions, i.e., x-direction (the previously described one lateral direction) and y-direction (the other lateral direction). The vertical direction (i.e., the z-direction) is perpendicular to the lateral surface and thus perpendicular to both the x-direction and the y-direction. The same notion for describing spatial relationships is applied throughout the present disclosure unless specified otherwise.

The semiconductor chip may be fabricated by photolithography, the details of which have been described in conjunction with FIG. 1. The top surface of the substrate may be etched through a photomask according to a designed pattern, which includes multiple contact holes 201 and multiple dummy holes 202, as shown in FIG. 2A. All of contact holes 201 and dummy holes 202 are designed to be in a square shape. Contact holes 201 are in contact with the electrical wiring of the semiconductor structure so that electrical signals are provided to or transferred out of the semiconductor structure. Each contact hole 201 is surrounded by three dummy holes 202, which are provided in the substrate to support the semiconductor structure and to prevent the bending of the electrical wiring in an area close to that contact hole 201, when external forces are exerted over a tolerable level.

FIG. 2B illustrates an enlarged top view of a semiconductor chip having a designed pattern 200. As shown in FIG. 2B, three dummy holes 202 are arranged in a triangular manner surrounding contact hole 201. The triangle may be an equilateral triangle, with the distances d₁ between any two of the three dummy holes 202 being the same.

FIG. 2C illustrates an enlarged top view of a semiconductor chip having a final pattern 210. Final pattern 210 is the pattern etched by photolithography on the surface of the semiconductor chip using a photomask having designed pattern 200. As shown in FIG. 2C, three dummy holes 212 are arranged in a triangular manner surrounding a contact hole 211. However, unlike designed pattern 200 in FIG. 2A, where all of contact holes 201 and dummy holes 202 have a square shape, contact holes 211 and dummy holes 212 of final pattern 210 are all of a round shape, as a result of diffraction, process effects, or other reasons commonly accompanying photolithography on a nanometer level. As the depth of etching grows, the cross-section size of round-shaped contact holes 211 and dummy holes 212 tend to shrink along the vertical direction. As a result, the cross-section size may be the smallest for both contact holes 211 and dummy holes 212 at their respective bottom of the etching. This may cause degradation of the support provided by dummy holes 212 to the semiconductor structure and increase bending of the electric wiring.

In some implementations, dummy holes and/or contact holes with larger areas are designed to counter these issues. Once etched onto a substrate, the hole diameter on the final pattern increases, and so does the diameter of any given cross-section along the etched channel of the substrate. However, this brings a new issue of reduced overlay shift window, measured as the shortest distance d₂ between a contact hole 201 and its adjacent dummy hole 202 on the designed pattern. During the fabrication process, the overlay shift window may disappear in the final pattern due to diffraction, process effects, etc., causing contact hole 211 and dummy hole 212 to partially merge. Thus, when contact hole 211 is subsequently filled in with conductive materials to form a channel structure to be connected to a conductive layer of a stacked structure, the filling materials may leak to the merged dummy hole, thus exposing the conductive layers to the extent that the electrical properties and structural robustness of the substrate are compromised.

The present disclosure introduces another solution to address the aforementioned issues in which a plurality of dummy channel structures extending vertically in a staircase area of a stack structure laterally formed on a substrate are provided, and a vertical projection of at least one of the dummy channel structures on a lateral surface of the substrate includes a two-dimensional shape with directionality, such as an eclipse. Thus, the overlay shift window between a dummy hole and its adjacent contact hole is increased, and the instances of unwanted merging of the two holes are greatly reduced or even eliminated during the fabrication process. Also, the electrical properties and structural robustness of the substrate are enhanced.

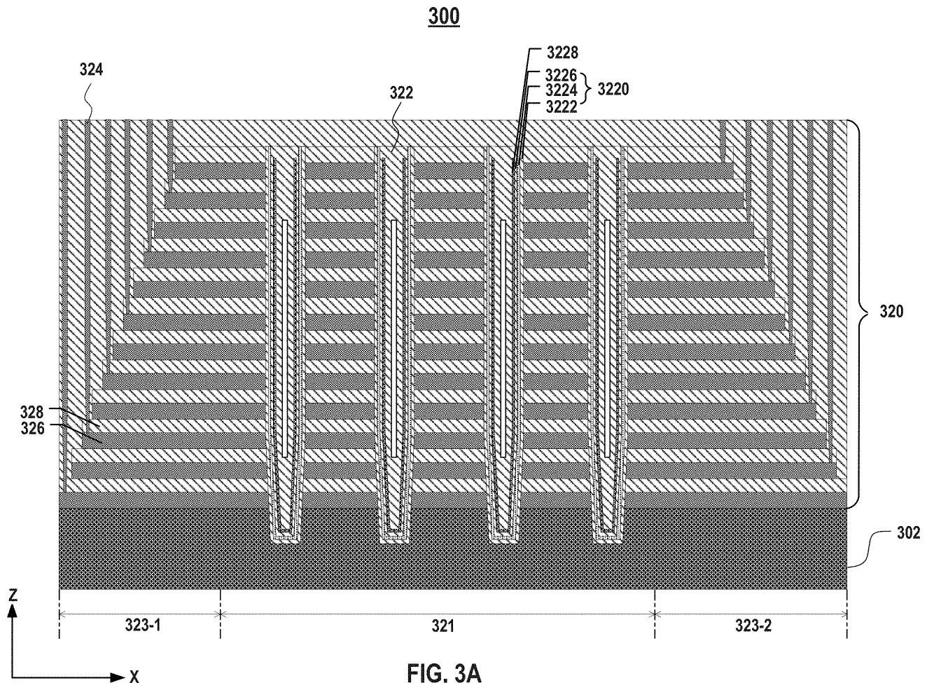

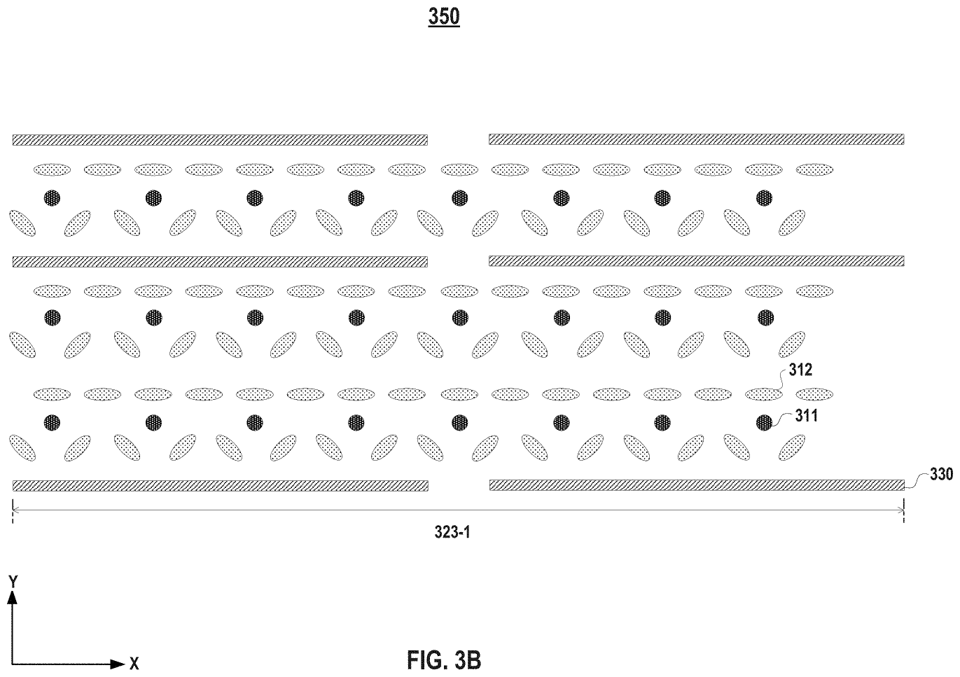

FIG. 3A illustrates a side view of a cross-section of an exemplary 3D memory device 300, according to some aspects of the present disclosure. It is noted that FIG. 3A shows 3D memory device 300 during a fabrication process, which may include a substrate 302 and a stack structure 320 laterally formed on substrate 302. Substrate 302 may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 302 is a thinned substrate (e.g., a semiconductor layer), which was thinned by grinding, etching, chemical mechanical polishing (CMP), or any combination thereof. Substrate 302 of 3D memory device 300 may include two lateral surfaces (e.g., a top surface and a bottom surface) extending laterally in the plane defined by the x-direction and the y-direction.

Consistent with the present disclosure, stack structure 320 may include a central area 321 in the middle and two staircase areas 323-1, 323-2 on the sides adjacent to central area 321. It is noted that although two staircase areas 323-1, 323-2 are shown in FIG. 3A, which only illustrates one cross-section of 3D memory device 300, the 3D memory device according to the present disclosure may include three or four staircase areas surrounding the central area. The two or more staircase areas are collectively referred to as staircase area 323. As will be further described in detail below, a plurality of channel structures 322 are formed in the central area, and a plurality of dummy channel structures (not shown) and a plurality of contact plugs 324 are formed in the staircase area.

According to the present disclosure, channel structures 322 may be formed in stack structure 320, extending vertically in central area 321. In some implementations, each channel structure 322 includes a memory film 3220, which in turn includes a tunneling layer 3226, a storage layer 3224 (also known as a “charge trap layer”), and a blocking layer 3222. Channel structure 322 may further include a semiconductor channel 3228, which is formed by filling in semiconductor material(s) in channel structure 322. In some implementations, channel structures 322 have a cylindrical shape, and semiconductor channel 3228 and tunneling layer 3226, storage layer 3224, and blocking layer 3222 of memory film 3220 are arranged radially from the center toward the outer surface of the cylinder in this order. A semiconductor plug (not shown) may be provided in the lower portion of channel structure 322 that is in contact with semiconductor channel 3228 and function as a channel controlled by a source select gate of channel structure 322.

In some implementations, stack structure 320 further includes a plurality of interleaved conductive layers 326 and dielectric layers 328 stacked vertically in a stepped manner in staircase area 323, as illustrated in FIG. 3A. Interleaved conductive layers 326 and dielectric layers 328 are part of a memory stack (not shown). The number of the pairs of conductive layers 326 and dielectric layers 328 in the memory stack determines the number of memory cells in 3D memory device 300. It is understood that in some implementations, the memory stack may have a multi-deck architecture (not shown), which includes a plurality of memory decks stacked over one another. The numbers of the pairs of conductive layers 326 and dielectric layers 328 in each memory deck may be the same or different.

Conductive layers 326 and dielectric layers 328 in stack structure 320 may alternate in the vertical direction. In other words, except the ones at the top or bottom of the memory stack, each conductive layer 326 may be adjoined by two dielectric layers 328 on both sides, and each dielectric layer 328 may be adjoined by two conductive layers 326 on both sides. Conductive layers 326 and dielectric layers 328 may form multiple steps in staircase area 323. Conductive layers 326 may include conductive materials including, but not limited to, tungsten (W), cobalt (Co), copper (Cu), aluminum (Al), Tantalum (Ta), polysilicon, doped silicon, silicides, or any combination thereof. Each conductive layer 326 may include a gate electrode (gate line) surrounded by an adhesive layer and a gate dielectric layer. The gate electrode of conductive layer 326 may extend laterally as a word line, ending at one or more staircase structures in staircase area 323. Each dielectric layer 328 may include dielectric materials including, but not limited to, silicon oxide, silicon nitride, silicon oxynitride, or any combination thereof. It may function as an insulation layer that separates conductive layers and/or lines from contacting each other, which would otherwise result in a short circuit or malfunction of the semiconductor device. Channel structures 322 may extend through a plurality of pairs each including a conductive layer 326 and a dielectric layer 328 (referred to herein as “conductive/dielectric layer pairs”). The number of the conductive/dielectric layer pairs in stack structure 320 (e.g., 32, 64, 96, or 128) determines the number of memory cells in 3D memory device 300.

In some implementations, 3D memory device 300 further includes a plurality of contact plugs 324 formed in staircase area 323 that are electrically connected to stack structure 320, as shown in FIG. 3A. Each contact plug 324 may extend vertically through stack structure 320 until it reaches and forms a contact with a conductive layer 326 of stack structure 320, therefore being electrically connected to conductive layer 326. The farther away a contact plug 324 is from central area 321 of stack structure 320, the larger depth that contact plug 324 extends vertically through stack structure 320 in order to reach its corresponding conductive layer 326. Contact plugs 324 may include one or more conductive layers, such as a metal layer (e.g., W, Co, Cu, Al, or Ta) or a silicide layer surrounded by an adhesive layer (e.g., TiN).

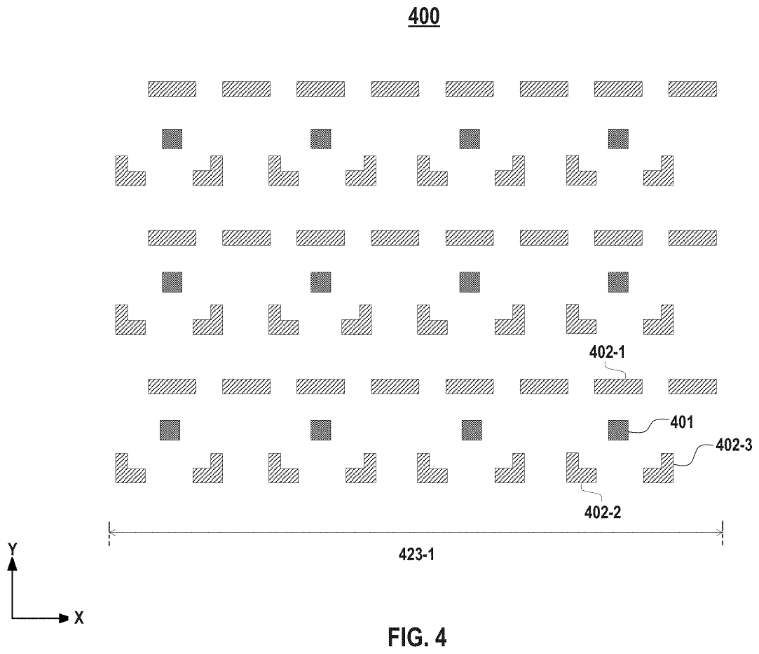

FIG. 3B illustrates an enlarged top view of an upper surface of 3D memory device 300 shown in FIG. 3A, according to some aspects of the present disclosure. The upper surface of 3D memory device 300 shows a pattern 350 in a staircase area 323-1, which is formed on the substrate of 3D memory device 300 by etching via photomask(s) with a designed pattern (to be described in conjunction with FIGS. 4A and 4B) different from pattern 200 shown in FIG. 2A, according to the present disclosure. Pattern 350 includes multiple arrays of contact holes 311 and multiple arrays of dummy holes 312. It is noted that once these holes are respectively filled in with conductive material(s) and dielectric material(s), they become contact plugs and dummy channel structures, respectively. Although only staircase area 323-1 is used as an exemplary implementation of the present disclosure, it is understood that the same dummy channel structure may be equally applied to other staircase area(s) or even a central area of a 3D memory device, according to the present disclosure.

Unlike the example shown in FIG. 2C, where dummy holes 212 of final pattern 210 are all of a round shape, dummy holes 312 according to the present disclosure may have a two-dimensional shape with directionality. As described above, the cross-section size of each dummy hole 312 tend to shrink towards the bottom of the etching, the vertical projection of a dummy channel structure, formed by filling in dummy hole 312 with an insulation material, on a lateral surface (e.g., top surface) of substrate 302 of 3D memory device 300 may be the same as the shape of dummy hole 312, as shown in FIG. 3C. According to the present disclosure, a shape with directionality includes a shape with at least two non-equidistant extensions in a two-dimensional coordinate. For example, in a plane defined by x-direction and y-direction, a shape with directionality may have an extension in the x-direction at a larger distance than an extension in the y-direction. In some implementations where the shape is a cone section, a shape with directionality may be a closed curve having an eccentricity between 0 and 1, exclusive. A shape with directionality may be a regular shape, such as eclipse, arc, fan, rectangular, trapezoid, diamond, bean-like shape, L shape, C shape, S shape, V shape, or W shape, or an irregular shape substantially similar to the regular shape.

In some implementations, dummy holes 312 have an eclipse shape, as shown in FIG. 3B. It is noted that such an eclipse shape also includes a shape substantially similar to an eclipse. The term “substantially,” when used in describing the shape of dummy holes or dummy channel structures, means the similarity between a shape, often irregular, and the closest regular shape it is compared to (e.g., eclipse, arc, fan, rectangular, trapezoid, diamond) is not smaller than 80% (e.g., 80%, 85%, 90%, 95%, 99%, 99.9%, any range bounded by the lower end by any of these values, or in any range defined by any two of these values). This is because sometimes the fabrication process may not be precise enough to make the hole shape of the final pattern exactly matching the intended pattern. Nevertheless, as long as the intended result of the present disclosure is obtained, it is not required to have an absolute matching of the final pattern and the intended pattern. In some implementations, the similarity may be measured by the size of overlapping areas of two shapes. For example, if the overlapping area accounts for 80% of the size of the shape, the similarity between that shape and its closest regular shape is deemed as 80%.

In some implementations, 3D memory device 300 further includes at least one gate separator 330. As shown in FIG. 3B, gate separators 330 may separate the substrate into multiple blocks. In some implementations, gate separators 330 continuously extend through central area 321 and staircase area 323. In other implementations, gate separators 330 discretely extend through the same areas, which means one or more gaps are created along the extended at least one gate separator 330. Multiple gate separators 330 may extend along a first direction (e.g., x-direction) parallelly while being aligned with distances from each other along a second direction (e.g., y-direction) perpendicular to the first direction, as shown in FIG. 3B. Same separation distances may bring unanimous width of the multiple blocks separated by gate separators 330.

According to the present disclosure, the final pattern that includes contact holes and dummy holes, such as final pattern 350, may be adjusted with various improvements. In some implementations, the dummy channel structures, created by filling in dummy holes 312 with an insulation material, may be arranged in a two-dimensional array, as shown in FIG. 3B. Similarly, contact plugs 324, created by filling in contact holes with a conductive material, may also be arranged in a two-dimensional array. Each row of the array of contact plugs 324 may be separated by one or more rows of the dummy channel structure array, as shown in FIG. 3B. Such an arrangement of dummy channel structures and contact plugs may provide structural support across the entirety of the substrate areas where such dummy channel structures and contact plugs are located. In some implementations, each contact plug 324 is surrounded by three or more dummy channel structures in staircase area 323. This offers an all-around protection of the vertical structure of contact plug 324 against undesired squeezing or bending forces created when stack structure 320 is fabricated to be very high, thus exerting tremendous pressure on the internal components of the substrate.

In some implementations, the three or more dummy channel structures may be equally separated along a circumference surrounding contact plug 324 on a lateral surface of stack structure 320. It is noted that the above should also include the scenario where the three or more dummy channel structures are substantially equally separated along the circumference. The term “substantially,” when used in describing the separation among the dummy channel structures, means the distances between adjacent dummy channel structures or angles towards contact plug 324 being surrounded do not vary above a range, such as ±10%. For example, when there are three dummy channel structures, they may be separated with 120 degrees between each pair of the adjacent dummy channel structures, such as being positioned in a triangular manner. Alternatively, when there are four dummy channel structures, they may be separated with 90 degrees between each pair of adjacent dummy channel structures, such as being positioned in a square or rectangular manner. This offers equal protection of the vertical structure of contact plug 324 against forces from all directions. In some implementations, a diameter of the circumference, along which the three or more dummy channel structures are equally separated, is equal to or less than half of the lateral distance between adjacent contact plugs 324. Therefore, the instances of overlapping between contact plug 324 and its surrounding dummy channel structures can be reduced.

FIG. 4 illustrates a top view of a semiconductor chip having a designed pattern 400, according to some aspects of the present disclosure. Designed pattern 400 may be used to generate pattern 350 (shown in FIG. 3B) on a top surface of the semiconductor chip by photolithography. Corresponding to pattern 350, designed pattern 400 may also have two-dimensional arrays respectively of contact holes 401 and of dummy holes 402. Although only staircase area 423-1 is used as an exemplary implementation of the present disclosure, it is understood that the same configuration may be equally applied to other staircase area(s) or even a central area of a 3D memory device, according to the present disclosure. As shown in FIG. 4, rows of contact holes 401 and rows of dummy holes 402 are staggered along a lateral direction (e.g., y-direction). Each pair of adjacent contact holes 401 may have two rows of dummy holes 402 in between.

In some implementations, each contact hole 401 is surrounded by three dummy holes 401-1, 402-2, 402-3. In other implementations, each contact hole 401 may be surrounded by four or more dummy holes, depending on the intended layouts to be created on the surface of the semiconductor chip. In the three-dummy-hole example, contact hole 401 may have a rectangular or square shape, while one dummy hole 402-1 may have a rectangular shape and the remaining two dummy holes 402-2, 402-3 may have an L shape, as shown in FIG. 4. The three dummy holes 402-1, 402-2, 402-3 may be positioned respectively at the three tips of a triangle. In some implementations, after being transferred to a photomask for etching the surface of the semiconductor chip, designed pattern 400 may be used to generate pattern 350 thereon. In some implementations, designed pattern 400 may include a regular shape or an irregular shape, such as eclipse, arc, fan, rectangular, trapezoid, diamond, bean-like shape, L shape, C shape, S shape, V shape, or W shape. In some implementations, OPC may be needed to correct certain contours of the various components on designed pattern 400 on the photomask, such as contact holes and/or dummy holes 402, in order to obtain the intended layouts of round contact holes and eclipse-shaped dummy holes on the surface of the semiconductor chip.

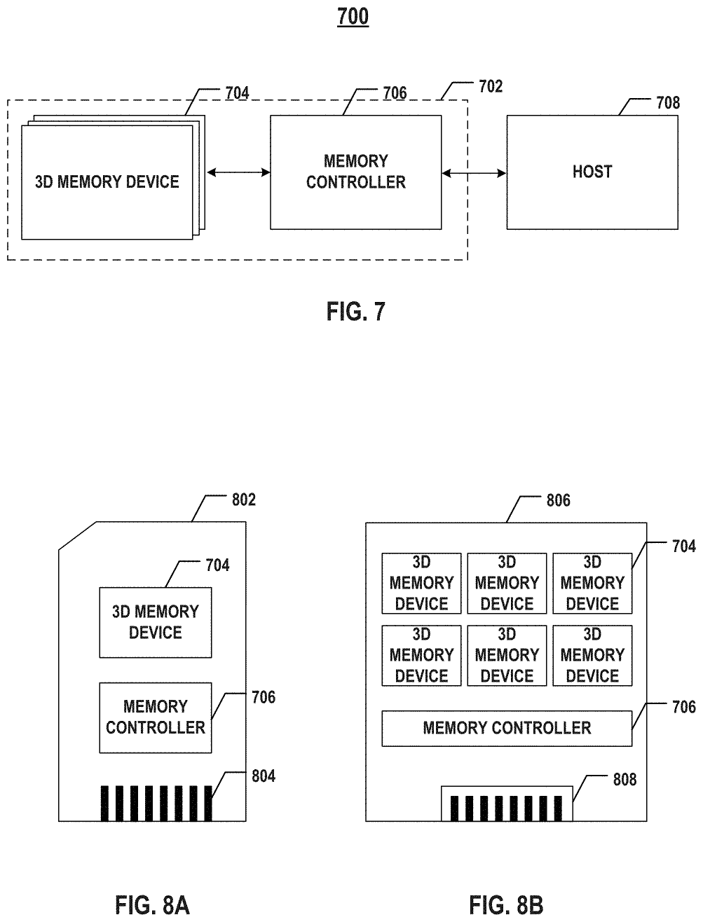

FIG. 7 illustrates a block diagram of an exemplary system 700 having a 3D memory device, according to some aspects of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, system 700 can include a host 708 and a memory system 702 having one or more 3D memory devices 704 and a memory controller 706. Host 708 can be a processor of an electronic device, such as a central processing unit (CPU), or a system-on-chip (SoC), such as an application processor (AP). Host 708 can be configured to send or receive data stored in memory device 704.

3D memory device 704 can be any 3D memory devices disclosed herein, such as 3D memory device 300 shown in FIG. 3A. In some implementations, each 3D memory device 704 includes a NAND Flash memory. Consistent with the scope of the present disclosure, 3D memory device 704 can be fabricated by forming a stack structure laterally on the substrate. The stack structure may have a central area and a staircase area. Subsequently, a plurality of dummy channel structures extending vertically in the staircase area and a plurality of channel structures extending vertically in the central area may be formed. The vertical projection of at least one of the dummy channel structures on a lateral surface of the substrate may include a two-dimensional shape with directionality. Therefore, the merging incidents of the dummy channel structures and the channel structures can be greatly reduced. As a result, the electric performance of 3D memory device 704 can be improved, which in turn improves the performance of memory system 702 and system 700, e.g., achieving more stable electrical properties and enhancing use cycles thereof.

Memory controller 706 is coupled to 3D memory device 704 and host 708 and is configured to control 3D memory device 704, according to some implementations. Memory controller 706 can manage the data stored in 3D memory device 704 and communicate with host 708. In some implementations, memory controller 706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed for operating in a high duty-cycle environment SSDs or embedded multi-media-cards (eMMCs) used as data storage for mobile devices, such as smartphones, tablets, laptop computers, etc., and enterprise storage arrays. Memory controller 706 can be configured to control operations of 3D memory device 704, such as read, erase, and program operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704. Memory controller 706 can communicate with an external device (e.g., host 708) according to a particular communication protocol. For example, memory controller 706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more 3D memory devices 704 can be integrated into various types of storage devices, for example, be included in the same package, such as a universal Flash storage (UFS) package or an eMMC package. That is, memory system 702 can be implemented as and packaged into different types of end electronic products. In one example as shown in FIG. 8A, memory controller 706 and a single 3D memory device 704 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, mini SD, microSD, SDHC), a UFS, etc. Memory card 802 can further include a memory card connector 804 electrically coupling memory card 802 with a host (e.g., host 708 in FIG. 7). In another example as shown in FIG. 8B, memory controller 706 and multiple 3D memory devices 704 may be integrated into an SSD 806. SSD 806 can further include an SSD connector 808 electrically coupling SSD 806 with a host (e.g., host 708 in FIG. 7). In some implementations, the storage capacity and/or the operation speed of SSD 806 is greater than those of memory card 802.

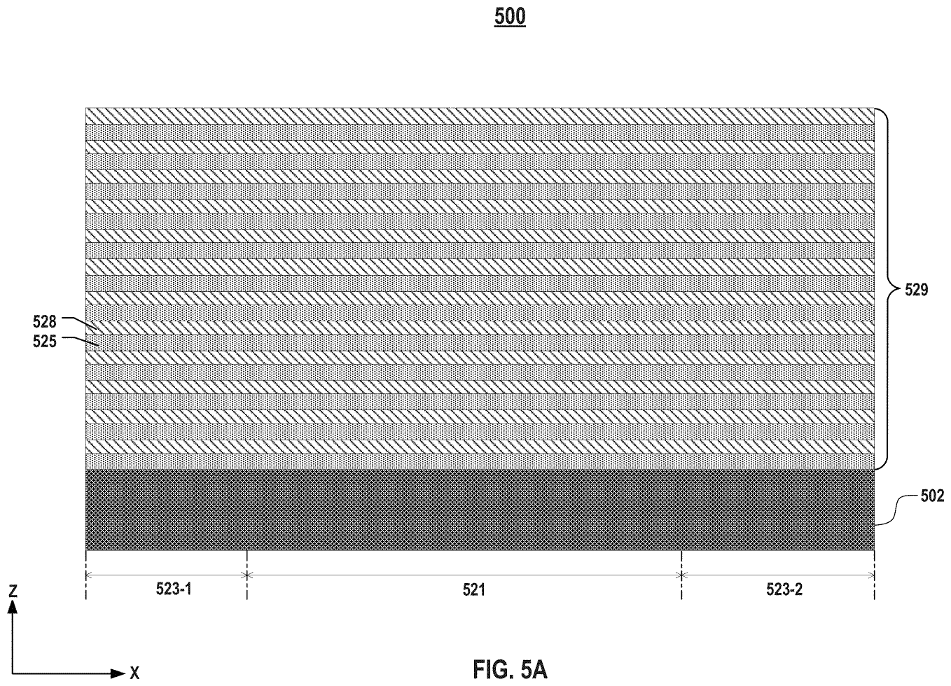

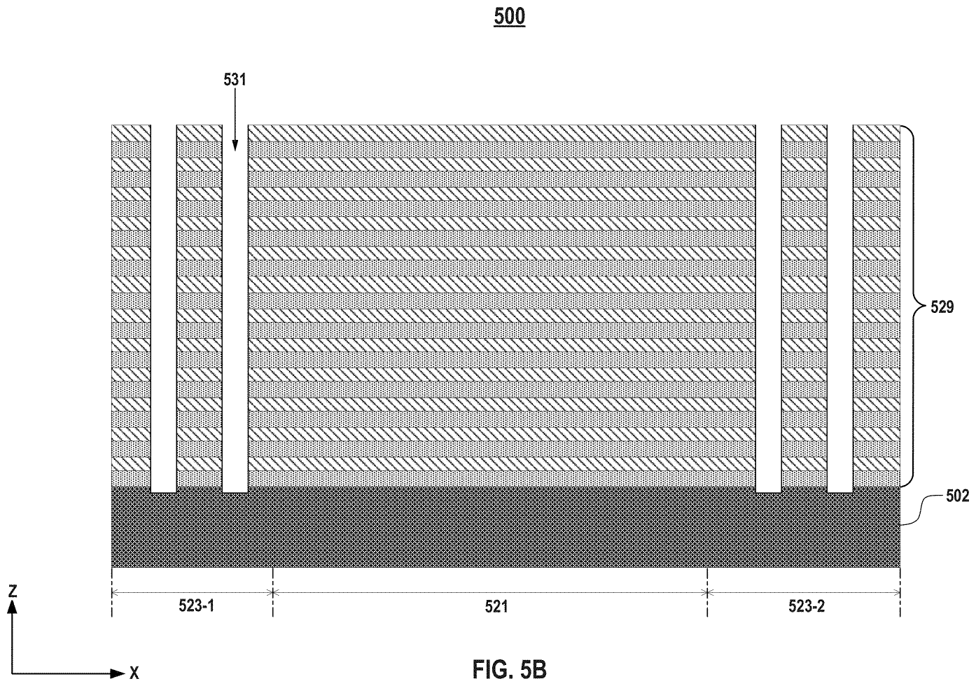

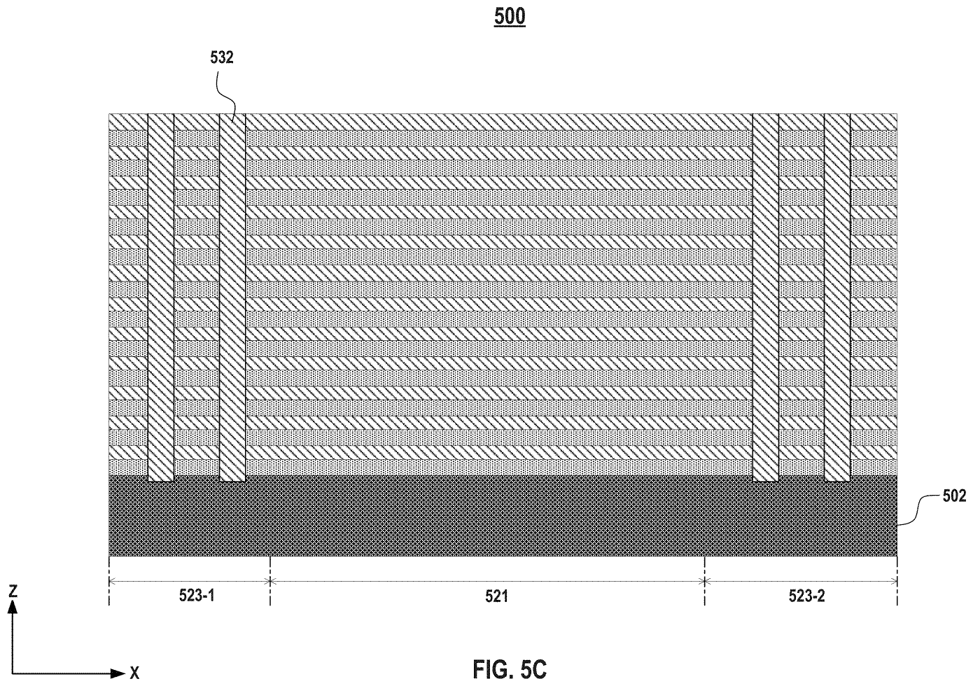

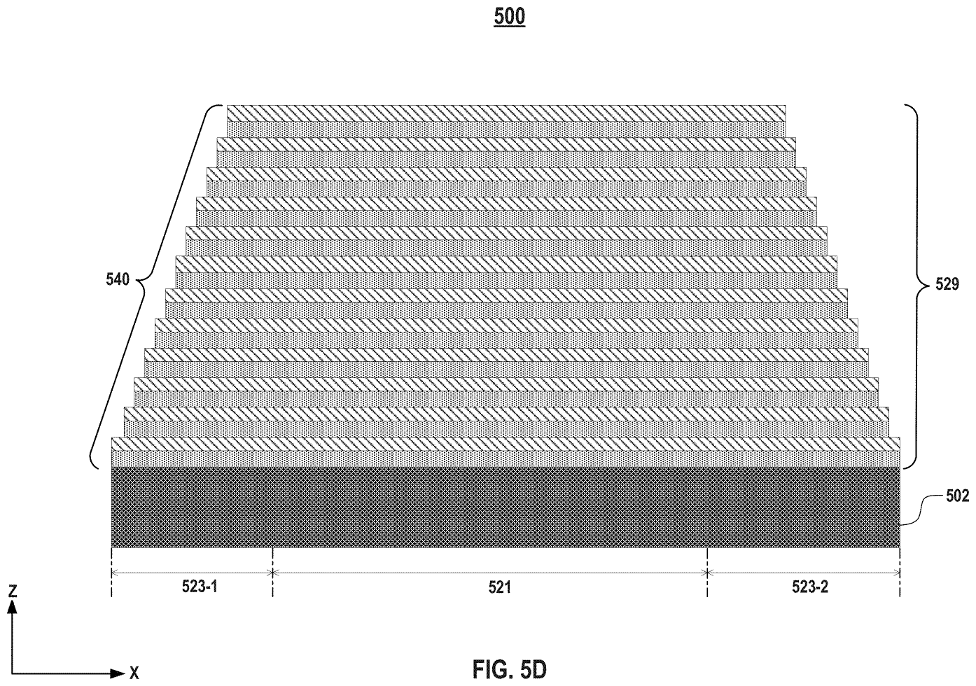

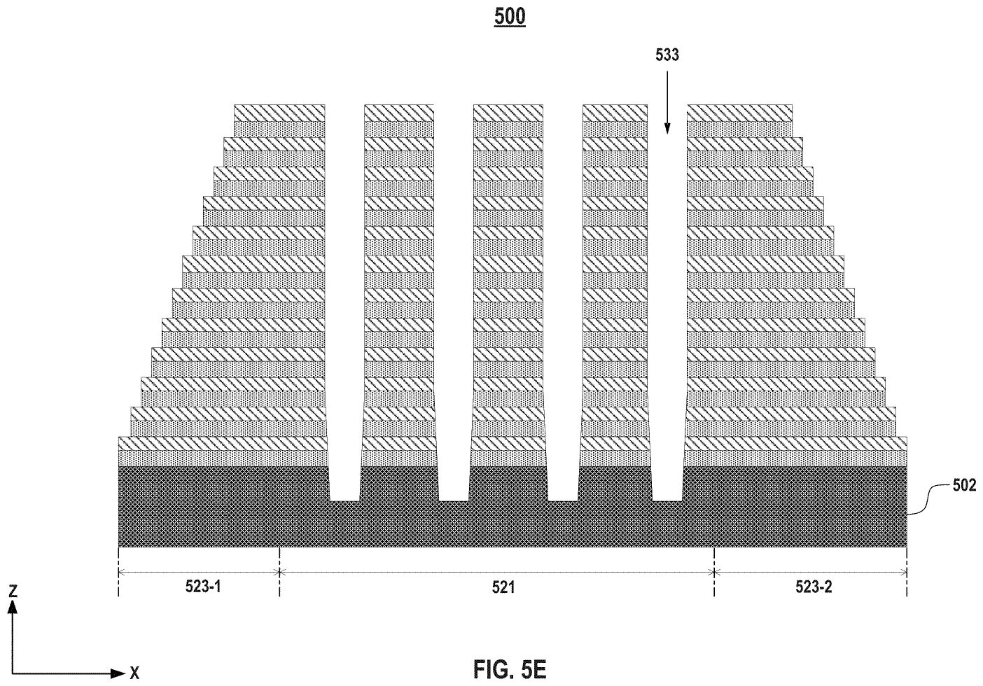

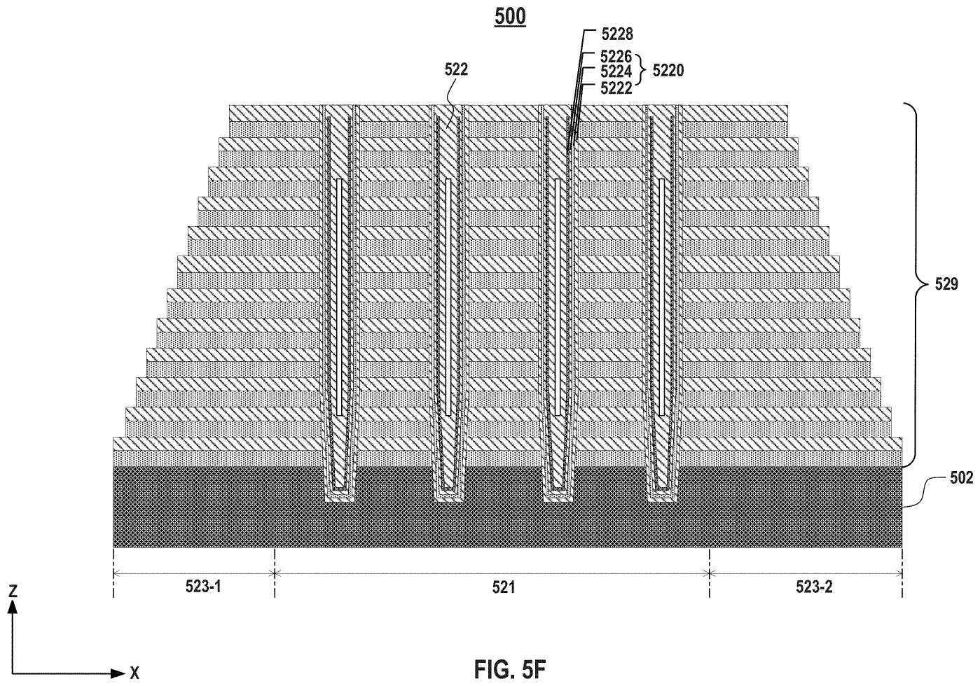

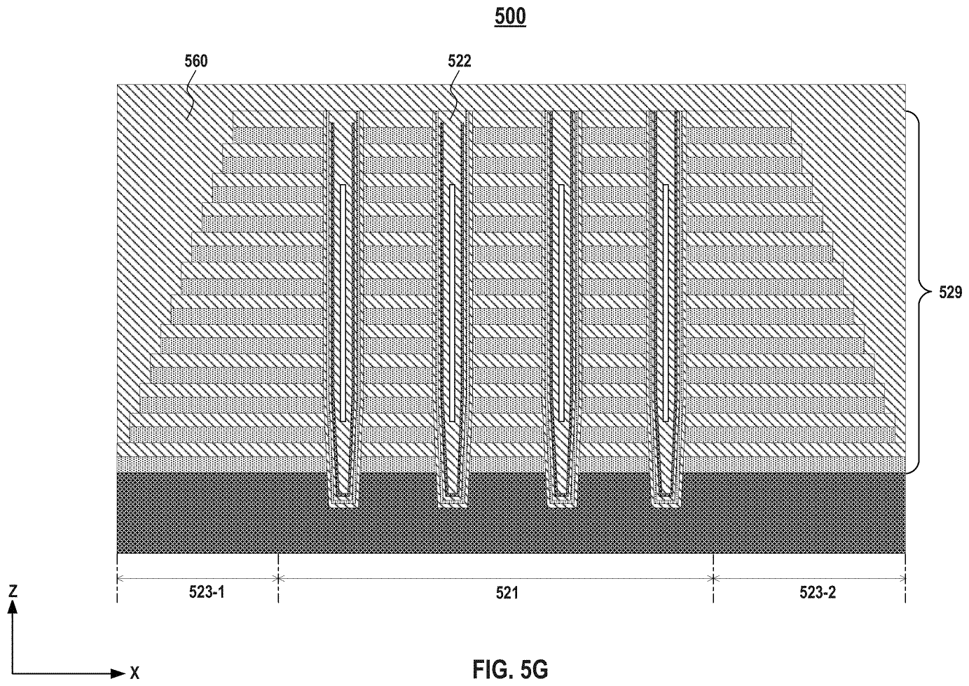

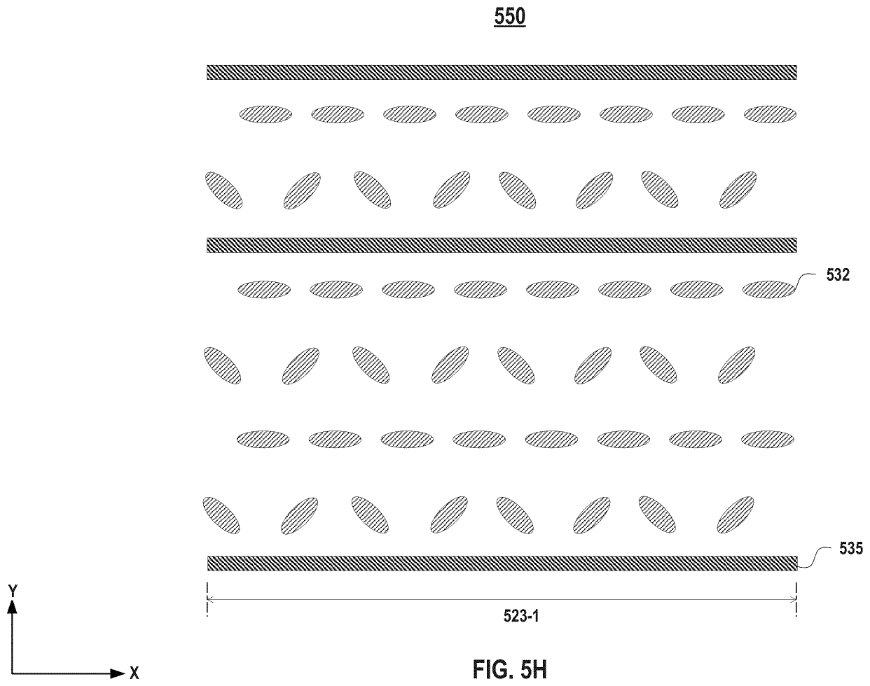

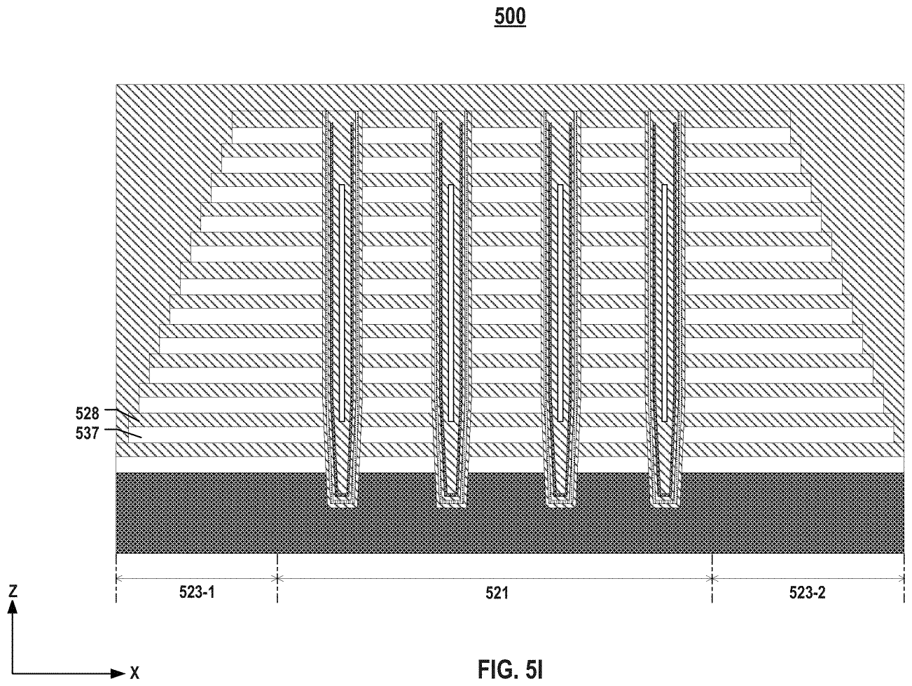

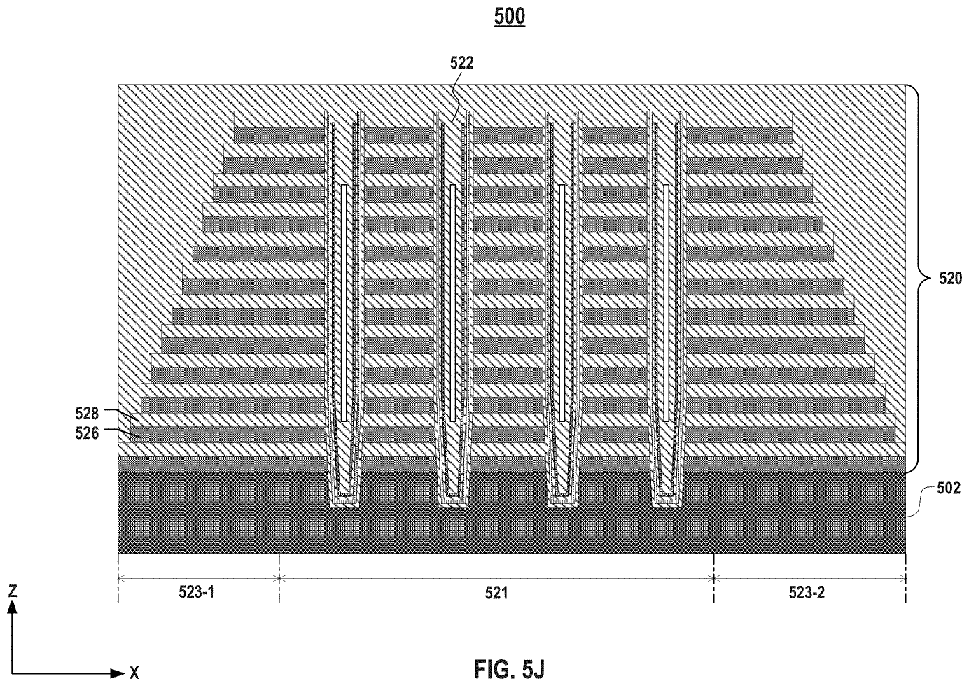

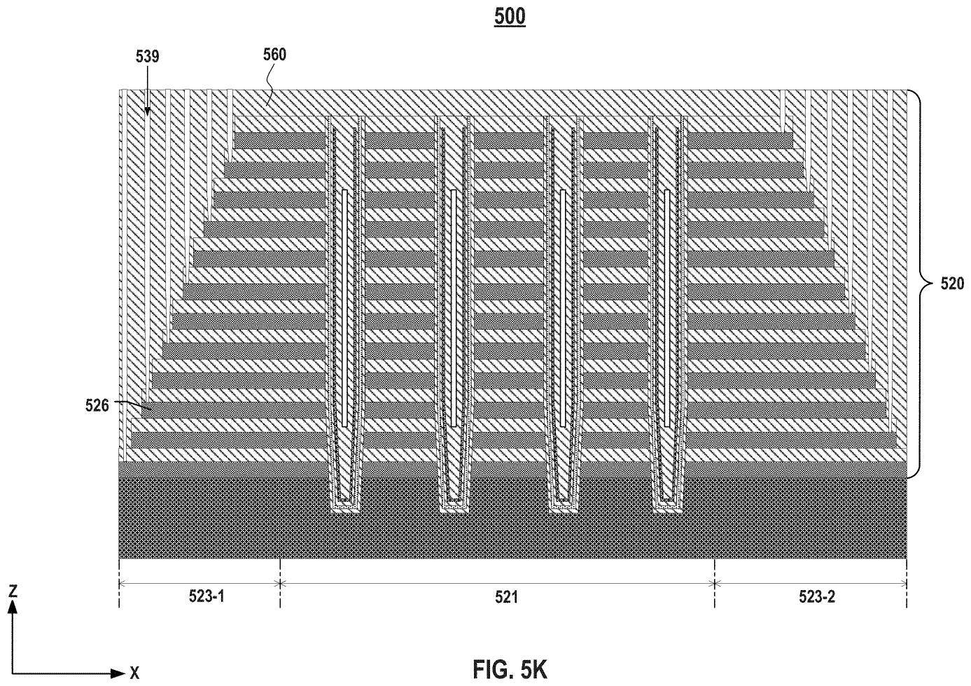

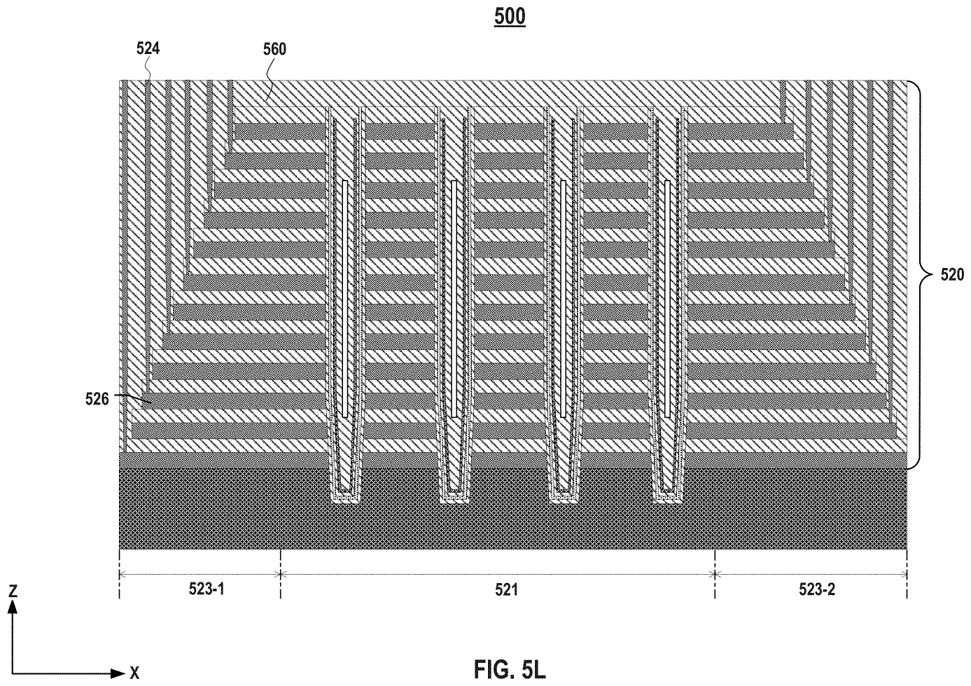

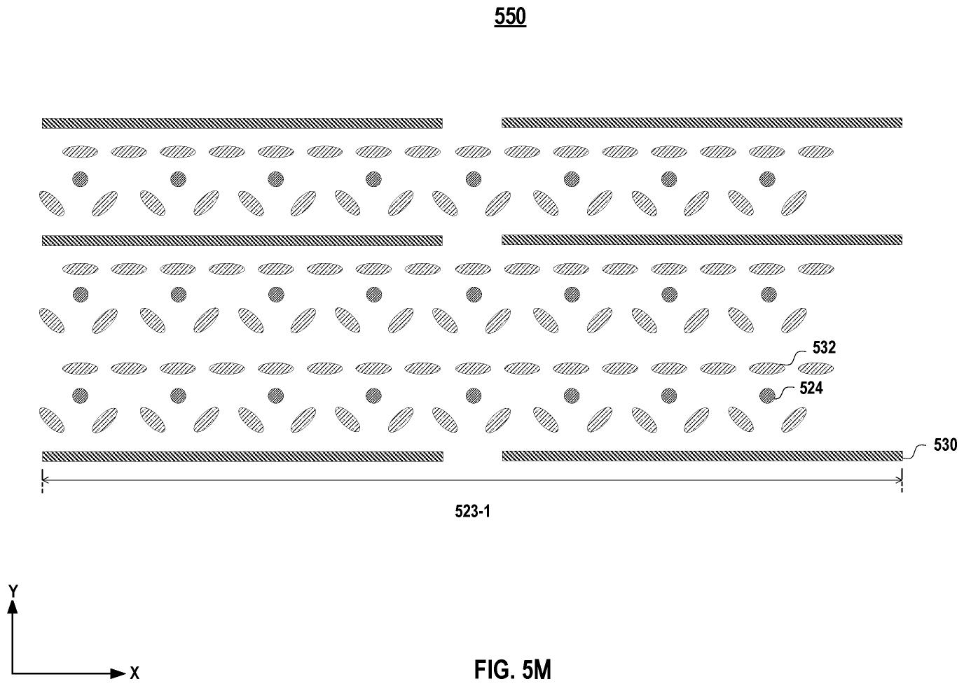

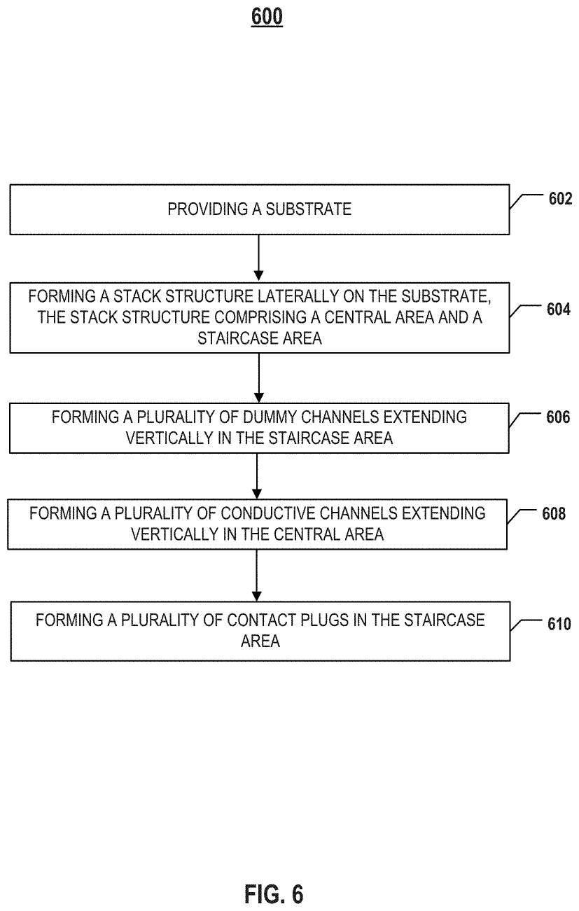

FIGS. 5A-5M illustrate a fabrication process for forming an exemplary 3D memory device 500, according to some implementations of the present disclosure. FIG. 6 illustrates a flowchart of a method 600 for forming exemplary 3D memory device 500, according to some implementations of the present disclosure. Examples of 3D memory device 500 depicted in FIGS. 5A-5M and 6 include 3D memory device 300 depicted in FIG. 3A. FIGS. 5A-5M and 6 will be described together. It is understood that the operations shown in method 600 are not exhaustive and that other operations can be performed as well before, after, or between any of the illustrated operations. Further, some of the operations may be performed simultaneously, or in a different order than shown in FIG. 6.

Referring to FIG. 6, method 600 starts at operation 602, in which a substrate 502 is provided. Substrate 502 may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 502 is a thinned substrate (e.g., a semiconductor layer), which was thinned by grinding, etching, chemical mechanical polishing (CMP), or any combination thereof. Substrate 502 of 3D memory device 500 may include two lateral surfaces (e.g., a top surface and a bottom surface) extending laterally in the plane defined by the x-direction and the y-direction, both of which are perpendicular to the z-direction. In some implementations, a stop layer (not shown) may be formed on the top surface of substrate 502 using one or more thin film deposition processes including, but not limited to, CVD, PVD, ALD, or any combination thereof. The stop layer may serve as an etch stopper. The stop layer may include any dielectric materials including, but not limited to, silicon oxide, silicon nitride, silicon oxynitride, low-k dielectrics, or any combination thereof. It is understood that in some examples, pad oxide layers (e.g., silicon oxide layers) may be formed between substrate 502 and the stop layer to relax the stress between different layers and avoid peeling. In other implementations, a subwavelength structure (SWS) layer may be formed on substrate 502. The SWS layer may include three semiconductor sub-layers, and the middle sub-layer is a sacrificial layer that may be replaced in subsequent steps.

Method 600 proceeds to operation 604, in which a stack structure may be formed on substrate 502, as shown in FIG. 5A. At the start of this operation, a dielectric stack 529 including a plurality pairs of a first dielectric layer 525 (referred to herein as “sacrificial layer”) and a second dielectric layer 528 (referred to herein as “dielectric layer,” together referred to herein as “dielectric layer pairs”) may be formed on substrate 502. Dielectric stack 529 may include interleaved sacrificial layers 525 and dielectric layers 528, according to some implementations. In some implementations, sacrificial layers 525 are subsequently replaced by conductive layers 526, which will be described in detail below. Dielectric layers 528 and sacrificial layers 525 can be alternatingly deposited on substrate 502 to form dielectric stack 529. In some implementations, each dielectric layer 528 includes a layer of silicon oxide, and each sacrificial layer 525 includes a layer of silicon nitride. Dielectric stack 529 can be formed by one or more thin film deposition processes including, but not limited to, CVD, PVD, ALD, or any combination thereof.

In some implementations, dielectric stack 529 may include a central area 521 in the middle and two staircase areas 523-1, 523-2 on the sides adjacent to central area 521. It is noted that although two staircase areas 523-1, 523-2 are shown in FIG. 5A, which only illustrates one cross-section of 3D memory device 500 in the middle of fabrication, 3D memory device 500 according to the present disclosure may include three or four staircase areas surrounding the central area. The two or more staircase areas are collectively referred to as staircase area 523. As will be further described in detail below, a plurality of channel structures 522 are formed in the central area, and a plurality of dummy channel structures (not shown) and a plurality of contact plugs 524 are formed in the staircase area.

Method 600 then proceeds to operation 606, in which a plurality of dummy channel structures are formed and extend vertically in staircase area 523. In some implementations, to form dummy channel structures in dielectric stack 529, a plurality of dummy holes 531 are etched vertically in staircase area 523. Dummy holes 531 may be etched in the places of dielectric stack 529 that are isolated from dielectric layer pairs (which are subsequently replaced by a plurality of interleaved conductive layers and dielectric layers). This brings the advantage of avoiding a potential short circuit by exposing the subsequently formed conductive layers.

According to the present disclosure, the etching of dummy holes 531 may be performed by using a photomask (not shown) having a same or similar designed pattern as designed pattern 400 in FIG. 4, thus resulting in dummy holes 531 that have a two-dimensional shape with directionality, which are the same as or similar to dummy holes 312 shown in FIG. 3B. In some implementations, the pattern of the photomask may be optimized by, for example, OPC, to obtain the two-dimensional shape. A shape with directionality may include a shape with at least two non-equidistant extensions in a two-dimensional coordinate. For example, in a plane defined by x-direction and y-direction, a shape with directionality may have an extension in the x-direction at a larger distance than an extension in the y-direction. In some implementations where the shape is a cone section, a shape with directionality may be a closed curve having an eccentricity between 0 and 1, exclusive. A shape with directionality may be a regular shape or an irregular shape, such as eclipse, arc, fan, rectangular, trapezoid, diamond, bean-like shape, L shape, C shape, S shape, V shape, or W shape. Fabrication processes for forming dummy holes 531 may include wet etching and/or dry etching, such as deep reactive ion etching (DRIE). Dummy holes 531 may be etched to pass through the entire height of dielectric stack 529 and reach substrate 502, as shown in FIG. 5B.

In some implementations, dummy holes 531 may be filled in with an insulation material to form the plurality of dummy channel structures 532, as shown in FIG. 5C. The insulation material may include, but not limited to, silicon oxide, silicon nitride, silicon oxynitride, low dielectric constant (low-k) dielectrics, or any combination thereof. The filled-in dummy channel structures 532 may additionally support the overall structural robustness of the stack structure and prevent the various internal components, such as to-be-formed word lines, from bending. In other implementations, dummy channel structures 532 may be formed in central area 521 as well, depending on the needs of the manufacturer and/or applications of 3D memory device 500. Similar to dummy holes 312 and the dummy channel structures formed therein, the cross-section size of each dummy channel structure 532 tend to shrink as the cross-section approaches substrate 502, and therefore the vertical projection of dummy channel structure 532 on a lateral surface (e.g., top surface) of substrate 502 may have the same shape as dummy hole 531, namely a two-dimensional shape with directionality. In some implementations, the two-dimensional shape may be an eclipse (shown in FIG. 5H). It is noted that such an eclipse shape also includes a shape substantially similar to an eclipse.

In some implementations, a staircase structure 540 can be formed in staircase areas 523-1, 523-2 of dielectric stack 529, as shown in FIG. 5D. Staircase structure 540 can be formed by performing a plurality of so-called “trim-etch” cycles to the dielectric layer pairs of dielectric stack 529 toward substrate 502. Due to the repeated trim-etch cycles applied to the dielectric layer pairs of dielectric stack 529, dielectric stack 529 can have one or more tilted edges and a top dielectric layer pair shorter than the bottom one.

Method 600 then proceeds to operation 608, in which a plurality of channel structures are formed and extend vertically in central area 521. As shown in FIG. 5E, a plurality of channel holes 533 are etched vertically in central area 521. In some implementations, a plurality of openings are formed, such that each opening becomes the location for growing an individual channel structure 522 in the later process (shown in FIG. 5F). Fabrication processes for forming channel holes 533 may include wet etching and/or dry etching, such as DRIE. The etching of channel holes 533 may continue until it reaches substrate 502. In some implementations, the etching conditions, such as etching rate and time, can be controlled to ensure that each channel hole 533 has reached substrate 502, sometimes with the help of the stop layer, to minimize the gouging variations among channel holes 533 and channel structures 522 formed therein.

In some implementations, each channel structure 522 can include a memory film 5220 and a semiconductor channel 5228. As shown in FIG. 5F, to form channel structure 522, memory film 5220 and semiconductor channel 5228 may be sequentially formed along a sidewall of and a bottom surface of channel hole 533. In some implementations, memory film 5220 may include a blocking layer 5222, a storage layer 5224, and a tunneling layer 5226. In some implementations, blocking layer 5222, storage layer 5224, and tunneling layer 5226 are first deposited along the sidewalls and bottom surface of channel hole 533 in this order using one or more thin film deposition processes, such as ALD, CVD, PVD, any other suitable processes, or any combination thereof, to form memory film 5220. Semiconductor channel 5228 then can be formed by depositing a semiconductor material, such as polysilicon (e.g., undoped polysilicon), over tunneling layer 5226 using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are sequentially deposited to form blocking layer 5222, storage layer 5224, and tunneling layer 5226 of memory film 5220 and semiconductor channel 5228.

In some implementations, a dielectric cover layer 560 may be formed on dielectric stack 529, as shown in FIG. 5G. In some implementations, dielectric cover layer 560 may cover at least staircase area 523. In some other implementations, dielectric cover layer 560 may cover both staircase area 523 and central area 521 in their entirety. Dielectric cover layer 560 may protect channel structures 522 from being damaged by subsequent fabrication processes. Subsequently, a plurality of gate separator slits 535 may be formed in and extend vertically through dielectric cover layer 560 and dielectric stack 529. In some implementations, fabrication processes for forming gate separator slits 535 include wet etching and/or dry etching, such as DRIE. In some implementations, gate separator slits 535 may extend laterally through both central area 521 and staircase area 523 in a first direction (e.g., x-direction) on a plane defined by x-direction and y-direction, as shown in FIG. 5H. Gate separator slits 535 may be spaced apart from each other along a second direction (e.g., y-direction) perpendicular to the first direction. Although continuous gate separator slits 535 are demonstrated in FIG. 5H, it is understood that discrete gate separator slits 535, which means one or more gaps are created along the extended gate separator slit 535, are also conceived according to the present disclosure.

Subsequently, a gate replacement process may be performed through gate separator slits 535 to replace dielectric stack 529 with a stack structure 520, also known as a memory stack (shown in FIG. 5J). Specifically, lateral recesses 537 are first formed by removing sacrificial layers 525 through gate separator slits 535, as shown in FIG. 5I In some implementations, sacrificial layers 525 are removed by applying etchants through gate separator slits 535, creating lateral recesses 537 interleaved between dielectric layers 528. The etchants can include any suitable etchants that etch sacrificial layers 525 selective to dielectric layers 528. Then, conductive layers 526 (including gate electrodes and adhesive layers) may be deposited into lateral recesses 537 through gate separator slits 535, as shown in FIG. 5J. In some implementations, a gate dielectric layer (not shown) is deposited into lateral recesses 537 prior to conductive layers 526, such that conductive layers 526 are deposited on the gate dielectric layer. Conductive layers 526, such as metal layers, can be deposited using one or more thin film deposition processes, such as ALD, CVD, PVD, any other suitable processes, or any combination thereof. In some implementations, the gate dielectric layer, such as a high-k dielectric layer, is formed along the sidewall and at the bottom of gate separator slits 535 as well. Stack structure 520 including interleaved conductive layers 526 and dielectric layers 528 is thereby formed, replacing dielectric stack 529, according to some implementations. In some implementations, a portion of substrate 502 is replaced with a conductive material via gate separator slits 535. Thus, substrate 502 may be electrically connected with channel structures 522. Subsequently, gate separator slits 535 may be filled in with an insulation material to form gate separators 530. Similar to gate separator slits 535, gate separators 530 may continuously or discretely extend through central area 521 and staircase area 523.

Method 600 then proceeds to operation 610, in which a plurality of contact plugs are formed in staircase area 523 and electrically connected to stack structure 520. In some implementations, a plurality of contact holes 539 may be formed by etching vertically in staircase area 523 of stack structure 520, as shown in FIG. 5K. Such formation process may include wet etching and/or dry etching, such as DRIE. Each contact hole 539 may be etched until its bottom reaches a conductive layer 526. Thus, an electrical connection may be established between word lines of stack structure 520 and peripheral circuits (not shown) of 3D memory device 500 via contact plugs 524, as shown in FIG. 5L, which are formed by filling in contact holes 539 with a conductive material using one or more thin film deposition processes, such as ALD, CVD, PVD, any other suitable processes, or any combination thereof. The contact material may include, but not limited to, W, Co, Cu, Al, silicides, or any combination thereof. In some implementations, the upper surfaces of contact plugs 524 are flush with the upper surface of dielectric cover layer 560.

FIG. 5M illustrates an enlarged top view of an upper surface of 3D memory device 500 after the formation of dummy channel structures 532 and contact plugs 524 in staircase area 523, according to some implementations of the present disclosure. The upper surface shows a pattern 550 in a staircase area 523-1. Pattern 550 includes multiple arrays of contact plugs 524 and multiple arrays of dummy channel structures 532. Although only staircase area 523-1 is used as an exemplary implementation of the present disclosure, it is understood that the same dummy channel structure may be equally applied to other staircase area(s) or even central area 521 of 3D memory device 500, according to the present disclosure.

Dummy channel structures 532 according to the present disclosure may have a two-dimensional shape with directionality. As described above, the cross-section size of each dummy channel structure 532 tend to shrink towards the bottom of the etching, the vertical projection of dummy channel structure 532 on a lateral surface (e.g., top surface) of substrate 502 of 3D memory device 500 may also have a two-dimensional shape with directionality. According to the present disclosure, a shape with directionality includes a shape with at least two non-equidistant extensions in a two-dimensional coordinate. For example, in a plane defined by x-direction and y-direction, a shape with directionality may have an extension in the x-direction at a larger distance than an extension in the y-direction. In some implementations where the shape is a cone section, a shape with directionality may be a closed curve having an eccentricity between 0 and 1, exclusive. A shape with directionality may be a regular shape or an irregular shape, such as eclipse, arc, fan, rectangular, trapezoid, diamond, bean-like shape, L shape, C shape, S shape, V shape, or W shape.

In some implementations, 3D memory device 500 further includes at least one gate separator 530. As shown in FIG. 5M, gate separators 530 may separate the substrate into multiple blocks. In some implementations, gate separators 530 continuously extend through central area 521 and staircase area 523. In other implementations, gate separators 530 discretely extend through the same areas, which means one or more gaps are created along the extended at least one gate separator 530. Multiple gate separators 530 may extend along a first direction (e.g., x-direction) parallelly while being aligned with distances from each other along a second direction (e.g., y-direction) perpendicular to the first direction, as shown in FIG. 5M. Same separation distances may bring unanimous width of the multiple blocks separated by gate separators 530.

According to the present disclosure, the final pattern that includes contact plugs and dummy channel structures, such as final pattern 550, may be adjusted with various improvements. In some implementations, dummy channel structures 532 may be arranged in a two-dimensional array, as shown in FIG. 5M. Similarly, contact plugs 524 may also be arranged in a two-dimensional array. Each row of the array of contact plugs 524 may be separated by one or more rows of the dummy channel structure array. In some implementations, there are certain adjacent rows of the dummy channel structure array between which no contact plug 524 is formed. Such an arrangement of dummy channel structures and contact plugs may provide structural support across the entirety of the substrate areas where such dummy channel structures and contact plugs are located. In some implementations, each contact plug 524 is surrounded by three or more dummy channel structures 532 in staircase area 523. This offers an all-around protection of the vertical structure of contact plug 524 against undesired squeezing or bending forces created when stack structure 520 is fabricated to be very high, thus exerting tremendous pressure on the internal components of the substrate.

In some implementations, three or more dummy channel structures 532 may be equally separated along a circumference surrounding contact plug 524 on a lateral surface of stack structure 520. It is noted that the above should also include the scenario where three or more dummy channel structures 532 are substantially equally separated along the circumference. For example, when there are three dummy channel structures 532, as shown in FIG. 5M, they may be separated with 120 degrees between each pair of adjacent dummy channel structures 532, such as being positioned in a triangular manner. Alternatively, when there are four dummy channel structures (not shown), they may be separated with 90 degrees between each pair of adjacent dummy channel structures, such as being positioned in a square or rectangular manner. This offers equal protection of the vertical structure of contact plug 524 against forces from all directions. In some implementations, a diameter of the circumference, along which three or more dummy channel structures 532 are equally separated, is equal to or less than half of the lateral distance between adjacent contact plugs 524. Therefore, the instances of overlapping between contact plug 524 and its surrounding dummy channel structures 532 can be reduced.

According to one aspect of the present disclosure, a 3D memory device includes a substrate, a stack structure laterally formed on the substrate and having a central area and a staircase area, a plurality of channel structures extending vertically in the central area, a plurality of dummy channel structures extending vertically in the staircase area, and a plurality of contact plugs formed in the staircase area and being electrically connected to the stack structure. A vertical projection of at least one of the dummy channel structures on a lateral surface of the substrate includes a two-dimensional shape with directionality.

In some implementations, the two-dimensional shape is an eclipse.

In some implementations, the 3D memory device further includes at least one gate separator continuously or discretely extending through the central area and the staircase area.

In some implementations, the stack structure includes a plurality of interleaved conductive layers and dielectric layers. The interleaved conductive layers and dielectric layers are stacked vertically in a stepped manner in the staircase area. Each contact plug is electrically connected to a conductive layer of the stack structure.

In some implementations, the dummy channel structures are arranged in a two-dimensional array. The contact plugs are arranged in a two-dimensional array with each row separated by one or more rows of the two-dimensional dummy channel structure array.

In some implementations, each contact plug is surrounded by three or more dummy channel structures in the staircase area.

In some implementations, the three or more dummy channel structures are equally separated along a circumference surrounding the contact plug on a lateral surface of the stack structure.

In some implementations, each contact plug is surrounded by three dummy channel structures positioned in a triangular manner.

In some implementations, each contact plug is surrounded by four dummy channel structures positioned in a square or rectangular manner.

In some implementations, a diameter of the circumference is equal to or less than half of the lateral distance between the contact plug and its adjacent contact plug.

According to another aspect of the present disclosure, a method for forming a 3D memory device is provided. A substrate is provided. A stack structure is formed laterally on the substrate and includes a central area and a staircase area. A plurality of dummy channel structures are formed and extend vertically in the staircase area. A vertical projection of at least one of the dummy channel structures on a lateral surface of the substrate includes a two-dimensional shape with directionality. A plurality of channel structures are formed and extend vertically in the central area. A plurality of contact plugs are formed in the staircase area and are electrically connected to the stack structure.

In some implementations, a plurality of interleaved sacrificial layers and dielectric layers are formed. The plurality of sacrificial layers are replaced with a plurality of conductive layers to form a plurality of interleaved conductive layers and dielectric layers.

In some implementations, a plurality of dummy holes are etched vertically in the staircase area of the stack structure. The dummy holes are filled in with an insulation material to form the plurality of dummy channel structures.

In some implementations, a photomask for etching the plurality of dummy holes is provided. The photomask includes a pattern with at least one shape selected from the group consisting of eclipse, arc, fan, rectangular, trapezoid, diamond, bean-like shape, L shape, C shape, S shape, V shape, or W shape.

In some implementations, the pattern of the photomask is optimized to obtain the two-dimensional shape with directionality as the vertical projection of at least one of the dummy channel structures on the lateral surface of the substrate.

In some implementations, the two-dimensional shape is an eclipse.

In some implementations, the dummy holes are etched in places of the stack structure that are isolated from the plurality of interleaved conductive layers and dielectric layers.

In some implementations, a plurality of channel holes are etched vertically in the central area of the stack structure. The channel holes are filled in with a semiconductor layer and a composite dielectric layer to form the plurality of channel structures.

In some implementations, a plurality of contact holes are etched vertically in the staircase area of the stack structure. A bottom of each contact hole exposes a conductive layer of the plurality of interleaved conductive layers and dielectric layers. The contact holes are filled in with a conductive material to form the plurality of contact plugs electrically connected to the stack structure.

In some implementations, the dummy channel structures are formed in a two-dimensional array. The contact plugs are formed in a two-dimensional array with each row separated by one or more rows of the two-dimensional dummy channel structure array.

In some implementations, no contact plug is formed between at least two adjacent rows of the two-dimensional dummy channel structure array.

In some implementations, each contact plug is surrounded by three or more dummy channel structures in the staircase area.

In some implementations, the three or more dummy channel structures are equally separated along a circumference surrounding the contact plug on a lateral surface of the stack structure.

In some implementations, each contact plug is surrounded by three dummy channel structures positioned in a triangular manner.

In some implementations, each contact plug is surrounded by four dummy channel structures positioned in a square or rectangular manner.

In some implementations, a diameter of the circumference is equal to or less than half of the lateral distance between the contact plug and its adjacent contact plug.

In some implementations, a dielectric cover layer is formed on at least the staircase area of the stack structure. A plurality of gate separator slits are formed and extend vertically through the dielectric cover layer and the stack structure. The gate separator slits laterally extend through the central area and the staircase area in a first direction and are spaced apart from each other along a second direction perpendicular to the first direction. The sacrificial layers are etched via the gate separator slits. The conductive layers are formed via the gate separator slits at locations where the sacrificial layers are etched.

In some implementations, at least a portion of the substrate is replaced with a conductive material via the gate separator slits to form an electrical connection between the channel structures and the substrate. The gate separator slits are filled in with an insulation material to form gate separators.

According to still another aspect of the present disclosure, a system includes a 3D memory device configured to store data and a memory controller coupled to the 3D memory device and configured to control the 3D memory device. The 3D memory device includes a substrate, a stack structure laterally formed on the substrate and having a central area and a staircase area, a plurality of channel structures extending vertically in the central area, a plurality of dummy channel structures extending vertically in the staircase area, and a plurality of contact plugs formed in the staircase area and being electrically connected to the stack structure. A vertical projection of at least one of the dummy channel structures on a lateral surface of the substrate includes a two-dimensional shape with directionality.

In some implementations, the system further includes a host coupled to the memory controller and configured to send or receive the data.

In some implementations, the two-dimensional shape is an eclipse.

In some implementations, the 3D memory device further includes at least one gate separator continuously or discretely extending through the central area and the staircase area.

In some implementations, the stack structure includes a plurality of interleaved conductive layers and dielectric layers. The interleaved conductive layers and dielectric layers are stacked vertically in a stepped manner in the staircase area. Each contact plug is electrically connected to a conductive layer of the stack structure.

In some implementations, the dummy channel structures are arranged in a two-dimensional array. The contact plugs are arranged in a two-dimensional array with each row separated by one or more rows of the two-dimensional dummy channel structure array.

In some implementations, each contact plug is surrounded by three or more dummy channel structures in the staircase area.

In some implementations, the three or more dummy channel structures are equally separated along a circumference surrounding the contact plug on a lateral surface of the stack structure.

In some implementations, each contact plug is surrounded by three dummy channel structures positioned in a triangular manner.

In some implementations, each contact plug is surrounded by four dummy channel structures positioned in a square or rectangular manner.

In some implementations, a diameter of the circumference is equal to or less than half of the lateral distance between the contact plug and its adjacent contact plug.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a substrate;
a stack structure laterally formed on the substrate and comprising a central area and a staircase area;
a plurality of channel structures extending vertically in the central area;
a plurality of dummy channel structures extending vertically in the staircase area; and
a plurality of contact plugs formed in the staircase area and being electrically connected to the stack structure,
wherein a vertical projection of at least one of the dummy channel structures on a lateral surface of the substrate comprises a two-dimensional shape with directionality.

2. The 3D memory device of claim 1, wherein the two-dimensional shape is an eclipse.

3. The 3D memory device of claim 1, further comprising at least one gate separator continuously or discretely extending through the central area and the staircase area.

4. The 3D memory device of claim 1, wherein the stack structure comprises a plurality of interleaved conductive layers and dielectric layers,
wherein the interleaved conductive layers and dielectric layers are stacked vertically in a stepped manner in the staircase area, and
wherein each contact plug is electrically connected to a conductive layer of the stack structure.

5. The 3D memory device of claim 1, wherein the dummy channel structures are arranged in a two-dimensional array, and
wherein the contact plugs are arranged in a two-dimensional array with each row separated by one or more rows of the two-dimensional dummy channel structure array.

6. The 3D memory device of claim 5, wherein each contact plug is surrounded by three or more dummy channel structures in the staircase area.

7. The 3D memory device of claim 6, wherein the three or more dummy channel structures are equally separated along a circumference surrounding the contact plug on a lateral surface of the stack structure.

8. The 3D memory device of claim 7, wherein a diameter of the circumference is equal to or less than half of the lateral distance between the contact plug and its adjacent contact plug.

9. A method for forming a three-dimensional (3D) memory device, comprising:
providing a substrate;
forming a stack structure laterally on the substrate, the stack structure comprising a central area and a staircase area;
forming a plurality of dummy channel structures extending vertically in the staircase area, wherein a vertical projection of at least one of the dummy channel structures on a lateral surface of the substrate comprises a two-dimensional shape with directionality;
forming a plurality of channel structures extending vertically in the central area; and
forming a plurality of contact plugs in the staircase area, the contact plugs being electrically connected to the stack structure.

10. The method of claim 9, wherein forming a stack structure further comprises:
forming a plurality of interleaved sacrificial layers and dielectric layers; and
replacing the plurality of sacrificial layers with a plurality of conductive layers to form a plurality of interleaved conductive layers and dielectric layers.

11. The method of claim 9, wherein forming the plurality of dummy channel structures further comprises:
etching a plurality of dummy holes vertically in the staircase area of the stack structure; and
filling in the dummy holes with an insulation material to form the plurality of dummy channel structures.

12. The method of claim 11, wherein forming the plurality of dummy channel structures further comprises:
providing a photomask for etching the plurality of dummy holes, wherein the photomask comprises a pattern with at least one shape selected from the group consisting of eclipse, arc, fan, rectangular, trapezoid, diamond, bean-like shape, L shape, C shape, S shape, V shape, or W shape.

13. The method of claim 12, wherein forming the plurality of dummy channel structures further comprises:
optimizing the pattern of the photomask to obtain the two-dimensional shape with directionality as the vertical projection of at least one of the dummy channel structures on the lateral surface of the substrate.

14. The method of claim 11, wherein the dummy holes are etched in places of the stack structure that are isolated from the plurality of interleaved conductive layers and dielectric layers.

15. The method of claim 9, wherein forming the plurality of channel structures further comprises:
etching a plurality of channel holes vertically in the central area of the stack structure; and
filling in the channel holes with a semiconductor layer and a composite dielectric layer to form the plurality of channel structures.

16. The method of claim 9, wherein forming the plurality of contact plugs further comprises:
etching a plurality of contact holes vertically in the staircase area of the stack structure, wherein a bottom of each contact hole exposes a conductive layer of the plurality of interleaved conductive layers and dielectric layers; and
filling in the contact holes with a conductive material to form the plurality of contact plugs electrically connected to the stack structure.

17. The method of claim 9, further comprising:
forming the dummy channel structures in a two-dimensional array; and
forming the contact plugs in a two-dimensional array with each row separated by one or more rows of the two-dimensional dummy channel structure array.

18. The method of claim 10, wherein replacing the sacrificial layers with the conductive layers further comprises:
forming a dielectric cover layer on at least the staircase area of the stack structure;
forming a plurality of gate separator slits extending vertically through the dielectric cover layer and the stack structure, wherein the gate separator slits laterally extend through the central area and the staircase area in a first direction and are spaced apart from each other along a second direction perpendicular to the first direction;
etching the sacrificial layers via the gate separator slits; and
forming the conductive layers via the gate separator slits at locations where the sacrificial layers are etched.

19. The method of claim 18, further comprising:
replacing at least a portion of the substrate with a conductive material via the gate separator slits to form an electrical connection between the channel structures and the substrate; and
filling in the gate separator slits with an insulation material to form gate separators.

20. A system, comprising:
a three-dimensional (3D) memory device configured to store data, the 3D memory device comprising:
a substrate;
a stack structure laterally formed on the substrate and comprising a central area and a staircase area;
a plurality of channel structures extending vertically in the central area;
a plurality of dummy channel structures extending vertically in the staircase area; and
a plurality of contact plugs formed in the staircase area and being electrically connected to the stack structure,
wherein a vertical projection of at least one of the dummy channel structures on a lateral surface of the substrate comprises a two-dimensional shape with directionality; and
a memory controller coupled to the 3D memory device and configured to control the 3D memory device.
